(19) United States
(12) Patent Application Publication
(10) Pub. No.: US 2024/0365523 A1
(43) Pub. Date: Oct. 31, 2024

(54) METHOD OF MOUNTING ELECTRONIC DEVICES AND PARTIALLY SHIELDED BOARD FOR MOUNTING ELECTRONIC DEVICES

(71) Applicant: NATIONAL INSTITUTE OF ADVANCED INDUSTRIAL SCIENCE AND TECHNOLOGY, Tokyo (JP)

(72) Inventors: Sei UEMURA, Tsukuba-shi (JP); Takashi NAKAMURA, Sendai-shi (JP); Masateru NISHIOKA, Sendai-shi (JP); Naoko UENO, Tsukuba-shi (JP)

(73) Assignee: NATIONAL INSTITUTE OF ADVANCED INDUSTRIAL SCIENCE AND TECHNOLOGY, Tokyo (JP)

(21) Appl. No.: 18/566,466

(22) PCT Filed: Apr. 28, 2022
(86) PCT No.: PCT/JP2022/019387

§ 371 Date: Dec. 1, 2023

(30) Foreign Application Priority Data
Jul. 14, 2021 (JP) 2021-116207

(51) Int. Cl. H05K 13/04; H05B 6/74; H05B 6/80; H05K 3/34; H05K 9/00

(52) U.S. Cl. CPC H05K 13/0465; H05B 6/74; H05B 6/80; H05K 3/3494; H05K 9/0028; H05K 2203/101

(57) ABSTRACT

A method of mounting electronic devices, including the steps of:
irradiating with microwaves a board for mounting electronic devices including a base, a plurality of solder parts on the base, and a plurality of electronic devices corresponding to the plurality of solder parts placed in contact with the plurality of solder parts, the microwave irradiation is performed in a state in which electromagnetic shielding is performed for some of the plurality of solder parts; and
heating and melting at least the solder parts for which the electromagnetic shielding is not performed by an action of a magnetic field of a standing wave formed by the microwave irradiation.

### FIELD OF THE INVENTION

The present invention relates to a method of mounting electronic devices, and a partially shielded board for mounting electronic devices.

### BACKGROUND OF THE INVENTION

By using microwaves, an object to be heated can be heated directly and in a short time using an internal heating method. For example, it is known that a microwave is used as a heating method when mounting electronic devices using solder. However, a spark occurs in some cases when a conductive material is irradiated with a microwave. The present inventors formed a standing wave with uniform and maximum electromagnetic field strength by microwave irradiation, and by utilizing magnetic loss or induced current due to the action of the magnetic field rather than the electric field of the standing wave, a microwave device that can heat an object to be heated with high efficiency without generating sparks has been developed (for example, Patent Document 1).

### CITATION LIST

### Patent Literatures

Patent Literature 1: WO 2021/095723

### SUMMARY OF THE INVENTION

### Technical Problem

When mounting electronic devices using solder, it is necessary to control the heating temperature and heating time according to the heat resistance of the electronic device to be mounted. In addition, electronic devices having different heat resistance may be soldered onto the same base. In this case, for example, it is conceivable that solder mounting may be performed by setting the heating temperature to a low temperature side in accordance with electronic devices having low heat resistance. However, when the heating temperature is set to a low temperature side, there are problems in that there are portions where the electronic device and the base cannot be bonded sufficiently, resulting in a decrease in yield, and it takes time to achieve sufficiently strong bonding.

Moreover, it is also conceivable that the solder heating temperature or heating time for each electronic device mounted on the same base may be controlled; however, there are constraints on improving production efficiency. Furthermore, in a case of applying microwave heating, microwaves are uniformly irradiated, and thus controlling the solder heating temperature or heating time for each electronic device on the same base is not expected.

An object of the present invention is to provide a method for mounting electronic devices and a partially shielded board for mounting electronic devices that make it possible to solder mount electronic devices having different heat resistances arranged on the same base with high efficiency and low damage by using magnetic field heating caused by a microwave standing wave.

### Means for Solving the Problems

The problems of the present invention can be solved by the following means:

[1]

A method of mounting electronic devices, including the steps of:
irradiating with microwaves a board for mounting electronic devices including a base, a plurality of solder parts on the base, and a plurality of electronic devices corresponding to the plurality of solder parts placed in contact with the plurality of solder parts, the microwave irradiation is performed in a state in which electromagnetic shielding is performed for some of the plurality of solder parts; and
heating and melting at least the solder parts for which the electromagnetic shielding is not performed by an action of a magnetic field of a standing wave formed by the microwave irradiation.
   [2]

The method of mounting electronic devices described in the above item [1], wherein, of the plurality of solder parts, the solder parts for which the electromagnetic shielding is not performed are heated and melted by the action of the magnetic field of the standing wave, and then, of the plurality of solder parts, the solder parts for which the electromagnetic shielding is performed are heated and melted under a milder heating condition than a heating condition of the solder parts for which the electromagnetic shielding is not performed.

[3]

The method of mounting electronic devices described in the above item [1], wherein, of the plurality of solder parts, the solder parts for which the electromagnetic shielding is not performed are heated and melted by the action of the magnetic field of the standing wave, and of the plurality of solder parts, the solder parts for which the electromagnetic shielding is performed are also heated and melted by the action of the magnetic field of the standing wave under a milder heating condition than a heating condition of the solder parts for which the electromagnetic shielding is not performed.

[4]

The method of mounting electronic devices described in the above item [2] or [3], wherein a low-temperature solder is used for the solder parts for which the electromagnetic shielding is performed of the plurality of solder parts.

[5]

The method of mounting electronic devices described in any one of the above items [1] to [4], wherein the base includes an electrode part, the electronic devices also include an electrode part, the heated and melted solder parts are solidified, and the electrode part of the base and the electrode parts of the electronic devices are electrically connected via the solidified solder parts.

[6]

The method of mounting electronic devices described in any one of the above items [1] to [5], wherein the electromagnetic shielding contains metal materials.

[7]

The method of mounting electronic devices described in any one of the above items [1] to [6], wherein the standing wave is TMₙ₁₀ (where n is an integer of 1 or more) mode or TE₁₀ₙ (where n is an integer of 1 or more) mode.

[8]

A partially shielded board for mounting electronic devices, including:
a base,
a plurality of solder parts on the base, and a plurality of electronic devices corresponding to the plurality of solder parts and placed in contact with the plurality of solder parts,
   wherein electromagnetic shielding is performed for some of the solder parts of the plurality of solder parts.
   [9]

The partially shielded board for mounting electronic devices described in above item [8], wherein, by action of a magnetic field of a standing wave of microwave waves, at least the solder parts for which the electromagnetic shielding is not performed are heated and melted.

The partially shielded board for mounting electronic devices described in the above item [8] or [9], wherein the solder parts for which the electromagnetic shielding is performed contains a low-temperature solder.

In the present invention, “mounting of electronic devices” refers to incorporating electronic devices into equipment or devices (for example, attaching electronic devices to a base).

In the present invention, the term “electronic devices” is not limited to electronic devices such as semiconductor elements and integrated circuits (ICs), but is also used in a broad sense to include passive elements such as resistors, capacitors, and inductors, sensors such as various measuring elements and imaging elements, optical elements such as light receiving elements and light emitting elements, and acoustic elements.

In the present invention, the term “solder” is used in a broader sense than usual. In other words, in the present invention, the “solder” does not necessarily have to be electrically conductive, and as long as the composition is such that the solder has a property of being able to be melted by heating above a certain temperature, and then solidified to allow direct or indirect connection of the base and the electronic devices, the solder is included as the “solder” in the present invention. In addition, the “solder” of the present invention also includes solder whose conductivity decreases or is lost when heated and melted.

In the present invention, the “electromagnetic shielding” should have the function of weakening electromagnetic waves to a desired level. That is, in the present invention, the term “electromagnetic shielding” includes both forms that completely block electromagnetic waves and forms that partially block electromagnetic waves.

In the present invention, a numerical range expressed using “to” means a range that includes the numerical values written before and after “to” as lower and upper limits. For example, when “A to B” is written, the numerical range is “A or more to B or less”.

### Effects of the Invention

According to the method of mounting electronic devices and the partially shielded board for mounting electronic devices of the present invention, it is possible to solder mount electronic devices having different heat resistances arranged on the same base with high efficiency and low damage by using magnetic field heating caused by a standing wave of a microwave.

### BRIEF DESCRIPTION OF DRAWINGS

FIG. 1 is a schematic explanatory diagram (side view) showing a state in which a mounting board with electromagnetic shielding performed for some of the solder parts is irradiated with microwaves, solder parts without electromagnetic shielding performed are melted and solidified by magnetic field heating, and then, the electromagnetic shielding is removed and microwave irradiation is performed under milder conditions, and the solder parts with electromagnetic shielding performed are also melted by magnetic field heating.

FIG. 2 is a diagram showing the state in FIG. 1 as viewed from above the mounting board. FIG. 2 also shows the state of the electronic devices and solder parts below the electromagnetic shielding using dashed lines.

FIG. 3 is a block diagram schematically showing an example of a preferred entire configuration of a microwave heating apparatus, and is a drawing showing a cavity resonator in schematic cross-sectional view.

FIG. 4 is a photograph substituted for a drawing, and shows a state in which both a silicon wafer with solder paste placed thereon (upper side in FIG. 4) and an aluminum foil box in which a silicon wafer with solder paste placed thereon is placed therein (lower side in FIG. 4) are placed on a glass epoxy resin substrate.

FIG. 5 is an explanatory diagram schematically showing the state shown in the photograph of FIG. 4, with the state inside the aluminum foil box also visible.

FIG. 6 shows the results of measuring a temperature distribution using a thermo camera when microwave irradiation and magnetic field heating were performed in the state shown in the photograph of FIG. 4.

FIG. 7 shows the results of measuring the temperature distribution in Experimental Example 1-2 using a thermo camera when only the aluminum foil box, in which a silicon wafer with solder paste placed thereon is placed therein, is placed on a glass epoxy resin substrate and subjected to magnetic field heating by microwave irradiation.

FIG. 8 shows the results of measuring the temperature distribution in Experimental Example 2-1 using a thermo camera when both a silicon wafer with solder paste placed thereon (lower side in FIG. 8) and a copper box in which a silicon wafer with solder paste placed thereon is placed therein (upper side in FIG. 8) are placed on a glass epoxy resin substrate and subjected to microwave irradiation and magnetic field heating.

FIG. 9 shows the results of measuring the temperature distribution in Experimental Example 2-2 using a thermo camera when only the copper plate box, in which a silicon wafer with solder paste placed thereon is placed therein, is placed on a glass epoxy resin substrate and subjected to magnetic field heating by microwave irradiation.

### MODE FOR CARRYING OUT THE INVENTION

### [Method of Mounting Electronic Devices]

Preferred embodiments of the method for mounting electronic devices of the present invention (hereinafter, also simply referred to as “the mounting method of the present invention”) will be described with reference to the drawings as appropriate. Note that in the drawings, the dimensions and scale of each part may differ from the actual size for convenience of explanation. In addition, the drawings may be shown schematically to facilitate understanding. Furthermore, the present invention is not limited to the forms shown below except as specified in the present invention.

The mounting method of the present invention is a method of solder mounting electronic devices onto a base by heating solder parts of an electronic device mounting board (hereinafter also simply referred to as a “mounting board”) and melting the solder parts. Through this mounting, an electronic device mounted board (a board on which electronic devices are mounted, and hereinafter, will also simply be referred to as a “mounted board”), in which electronic devices are fixed onto the base, is obtained.

In the mounting method of the present invention, the above-mentioned mounting board includes a base, a plurality of solder parts on the base, and a plurality of electronic devices corresponding with the plurality of solder parts and arranged in contact with the plurality of solder parts. In addition, of the plurality of solder parts of the mounting board, electromagnetic shielding is performed for some of the solder parts so as to cover at least the solder parts and the electronic devices in contact with the solder parts. That is, the mounting board used in the present invention is a partially shielded board for mounting electronic devices. By irradiating the partially shielded board for mounting electronic devices with microwaves so as to form a standing wave, at least the solder parts without electromagnetic shielding performed are heated and melted by the action of the magnetic field of the standing wave (hereinafter, heating due to the action of a magnetic field of a standing wave is also referred to as “magnetic field heating”).

As the above-described mode of the standing wave, TMₙ₁₀ (n is an integer of 1 or more) modes (for example, modes of TM₂₁₀, TM₃₁₀) and TE₁₀ₙ (n is an integer of 1 or more) modes are included. As described below, the above described standing wave is preferable in TM₁₁₀ mode in the respect that the portion of the maximum magnetic field strength can be efficiently formed along the central axis of the cavity resonator.

In the case of a TE₁₀ₙ (n is an integer of 1 or more) mode, a TE₁₀₁ mode where n=1 is preferable, or TE₁₀₂ and TE₁₀₃ modes are also acceptable.

By placing the mounting board at the portion of the maximum magnetic field strength or at a surrounding area thereof (portion where the magnetic field strength is sufficient to melt the solder parts), at least solder parts without electromagnetic shielding performed can be heated and melted with high efficiency.

Examples of magnetic field heating caused by microwave irradiation include, for example, heat generation due to eddy current loss (resistance due to induced current) generated by the magnetic field, and heat generation due to magnetic loss generated by the magnetic field. The former is able to utilize heat generation from non-magnetic metal, and the latter is able to utilize heat generation from magnetic material. Magnetic field heating is described in detail in, for example, WO 2021/095723 A, and WO 2019/156142 A, and the like and these can be appropriately referred to in implementing the present invention.

In the mounting method of the present invention, the solder parts may be heated by a magnetic field acting directly on the solder parts, or may be heated indirectly by a heat generating part that is heated directly by the action of the magnetic field. The heat generating part can be configured to correspond to each solder part and come into contact with each solder part. A mounting method having such a heat generating part is itself publicly known, and for example, reference can be made to WO 2021/095723 A, WO 2019/156142 A, and the like.

The base constituting the mounting board used in the present invention is preferred to be formed of a dielectric material, such as a resin, an oxide, and ceramics, easily transmitting the microwave. For example, the base may be a thin material (for example, a sheet and a tape) such as a film and paper, and may be a plate-shaped body having a certain degree of thickness such as a resin substrate, a ceramic substrate, a glass substrate, and an oxide substrate. A metal plate can be used for the base. Further, the base may be one in which a surface of a metal plate is coated with the dielectric material.

As the resin capable of constituting the base, for example, polyimide, polyethylene terephthalate (PET), polytetrafluoroethylene (PTFE), polyethylene naphthalate (PEN), epoxy resins, and the like are included. As the oxide or the ceramics that can constitute the base, for example, silicon oxide (SiO₂), iron oxide (Fe₂O₃), tin oxide (SnO), titanium oxide (TiO₂), silicon nitride (SiN), aluminum oxide (Al₂O₃), silicon oxide (SiO₂), iron oxide (Fe₂O₃), tin oxide (SnO), titanium oxide (TiO₂), manganese chloride (MnCl₂), and the like are included. As the metal plate, an aluminum plate, a copper plate, and the like are included.

The base preferably has heat resistance of the melting point or more of solder.

The base may have a single layer structure or a multilayer structure. In a case of a multilayer structure, it is also preferable to use, for example, a metal-clad laminate (for example, a copper-clad laminate) as the base.

The solder parts of the mounting board are made of solder. There are no particular restrictions on the type of solder, and any solder used for solder mounting may be used as appropriate according to the purpose. In addition, as mentioned above, in the present invention, the “solder” does not necessarily have to be electrically conductive, and as long as the composition is such that the solder has a property of being able to be melted by heating above a certain temperature, and then solidified to allow direct or indirect connection of the base and the electronic device, the solder may be used as a solder in the present invention. That is, materials that serve an adhesive function by heating and melting and then solidifying are included in the “solder” of the present invention.

In a preferred embodiment of the mounting method of the present invention (hereinafter referred to as Embodiment 1), only the solder parts without electromagnetic shielding performed are heated and melted by the above magnetic field heating. For example, by providing electromagnetic shielding, which substantially blocks microwaves, to solder parts on which heat-sensitive electronic devices are placed, thermal damage to the electronic devices may be avoided. By exposing the solder parts on which heat-sensitive electronic devices are placed to milder heating conditions after removing the electromagnetic shielding, solder mounting may be performed while suppressing thermal damage to the electronic devices. In other words, the solder parts without electromagnetic shielding performed are heated and melted instantaneously at once by microwave irradiation to mount the electronic devices with high efficiency, and then the electromagnetic shielding of the solder parts with electromagnetic shielding performed is removed and solder mounting can be performed under milder heating conditions on the solder parts from which the electromagnetic shielding has been removed. A method for creating the mild heating conditions is not particularly limited, and for example, may include a method of irradiating microwaves with suppressed irradiation energy. Moreover, heating methods other than the microwave irradiation (for example, electric furnace heating, hot air heating, infrared heating, combined hot air/infrared heating, laser heating, high frequency heating, vapor phase soldering heating, flow heating, reflow heating, soldering iron heating, hot air heating, and the like) may also be employed.

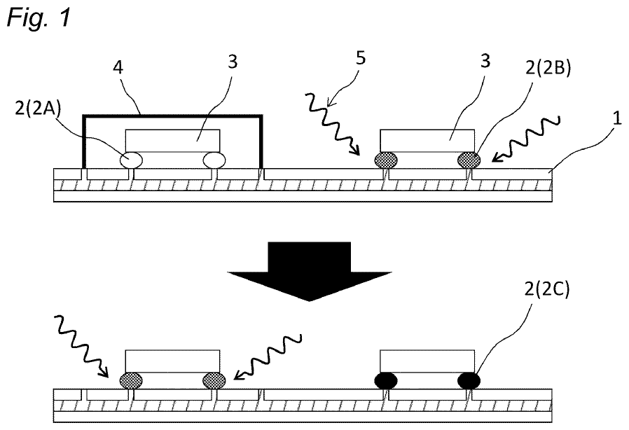

FIG. 1 schematically shows a form in which the mounting board is irradiated with microwaves and the solder parts are melted by magnetic field heating in Embodiment 1 described above.

FIG. 1 is an explanatory diagram schematically showing a mounting board as viewed from the side, and shows a form of a mounting board in which a copper-clad laminate is used as the base 1, solder parts 2 are placed on the base 1, and electronic devices 3 are placed in contact with the solder parts 2 and the mounting board is irradiated with microwaves 5 to melt (2B) and solidify (2C) the solder parts 2 without electromagnetic shielding performed by magnetic field heating. This mounting board is provided with electromagnetic shielding 4 so as to cover a portion 2A of the solder parts 2. This electromagnetic shielding 4 partially utilizes a copper portion of a copper-clad laminate (an intermediate layer portion of the base 1). Examples of shielding materials other than the copper portion of the copper-clad laminate used as the base 1 include materials including metals (copper, aluminum, gold, silver, nickel, zinc, brass, stainless steel, phosphor bronze, lead, and the like), graphite, graphene, conductive glass, conductive polymers, conductive glass, and conductive ceramics (antimony-doped tin oxide, etc.); and more preferably include metal materials.

In this way, in the mounting method of the present invention, a metal-clad laminate (preferably a copper-clad laminate) in which conductive metal foil such as copper is incorporated is applied as the base, and this metal foil may be used as a part of the electromagnetic shielding.

Note that the electromagnetic shielding may be arranged to cover the entire base, solder parts and electronic devices. That is, the electromagnetic shielding can be appropriately arranged to reduce the amount of magnetic field energy that directly or indirectly reaches the solder parts.

As shown in FIG. 1, microwaves 5 are irradiated onto a mounting board to which electromagnetic shielding 4 is performed for parts 2A of the solder parts 2 to form a standing wave, and by placing the solder parts in a portion of the standing wave where the magnetic field energy is sufficiently high, solder parts 2B in the portion where the electromagnetic shielding 4 is not performed can be heated and melted instantaneously and with high efficiency, and an electronic device can be solder mounted using the solder parts 2B.

In the form shown in FIG. 1, the solder parts 2A with electromagnetic shielding 4 performed do not melt because the magnetic field energy does not reach the inside of the electromagnetic shielding, or does not reach the inside of electromagnetic shielding sufficiently, and thus the electronic device 3 in contact with the solder parts 2A may also be protected from heat. In addition, the electromagnetic shielding is able to protect circuits within an electronic device from damage caused by electromagnetic energy. Then, by removing the electromagnetic shielding 4 from the solder parts with electromagnetic shielding 4 performed, solder mounting can be performed for the solder parts 2A from which the electromagnetic shielding 4 has been removed under milder heating conditions. As the solder parts 2A with electromagnetic shielding 4 performed, it is also possible to use, for example, low-temperature solder (in the present invention, “low-temperature solder” is a solder with a melting point of 190° C. or lower, preferably 180° C. or lower, and the melting point may be 170° C. or lower, or 160° C. or lower. The melting point of the low-temperature solder is usually 120° C. or higher, preferably 130° C. or higher, and may be 140° C. or higher).

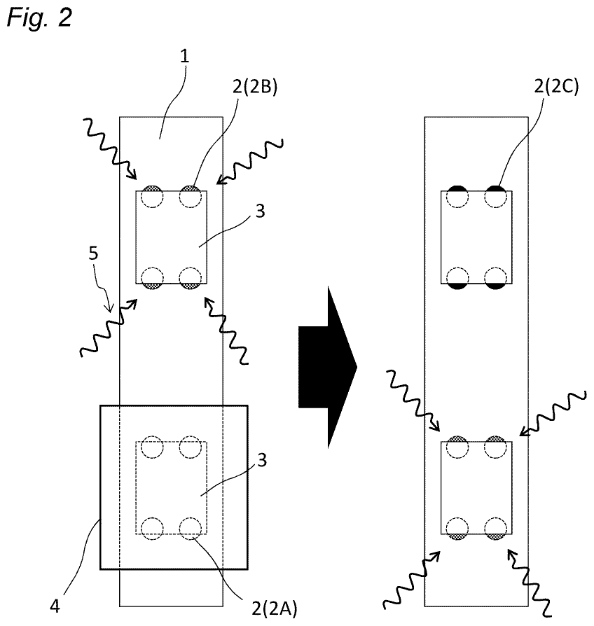

In this way, with the mounting method of the present invention, for solder parts on which relatively heat-resistant electronic devices are placed, microwave magnetic field heating instantly and efficiently heats and melts the solder parts, whereas solder parts on which heat-sensitive electronic devices are placed can be protected from this magnetic field heating. Then, by removing the electromagnetic shielding, solder mounting can be performed for the solder parts from which the electromagnetic shielding has been removed under milder heating conditions (for example, milder microwave magnetic field heating). FIG. 2 is an explanatory diagram schematically showing the form of FIG. 1 as viewed from above the mounting board, and includes the state of the solder parts inside the shielding and under the electronic device.

The means for subjecting the mounting board to magnetic field heating using a microwave standing wave (microwave heating apparatus) is not particularly limited, and a wide range of ordinary methods can be applied. A form of the microwave heating apparatus suitable for the mounting method of the present invention will be described later.

In another preferred embodiment (hereinafter referred to as Embodiment 2) of the mounting method of the present invention, in addition to the solder parts without electromagnetic shielding performed, the solder parts with electromagnetic shielding performed are also heated and melted in a lower temperature range by the above-described magnetic field heating. It has been found that the magnetic field energy that reaches the inside the shielding of the portion for which electromagnetic shielding has been performed can be controlled according to the state of the electromagnetic shielding, as will be shown in Examples described later. Therefore, the magnetic field energy that reaches inside the shielding of the portion for which electromagnetic shielding has been performed is relatively smaller than the magnetic field energy that reaches the solder parts without electromagnetic shielding performed; however, it is also possible to heat the solder to a temperature that melts the solder. As a result, it becomes possible to solder mount the electronic devices under milder conditions while suppressing thermal damage to the electronic devices that are in contact with the solder parts with electromagnetic shielding performed.

Depending on the state of the electromagnetic shielding, methods for controlling the magnetic field energy that reaches inside the shielding of the portion for which electromagnetic shielding has been performed include, for example, a method of creating gaps and/or holes in a part of the electromagnetic shielding, a method of appropriately using materials with relatively low shielding ability as electromagnetic shielding (such as zinc, brass, stainless steel, phosphor bronze, lead, and the like), graphite, graphene, conductive glass, conductive polymers, conductive glass, and conductive ceramics (such as antimony doped tin oxide), a method of manipulating the thickness of the sheet or thin film used for the shielding, and a method of adding, coating, or laminating a dielectric or magnetic material or both. In addition, by combining the control of the energy and heating time of the irradiated microwaves and the control of microwave irradiation with a pulse waveform and the conveying speed of the mounting board, it becomes possible to more flexibly adjust the amount of magnetic field energy that reaches inside the electromagnetic shielding.

In Embodiment 2 described above, an electronic device A, which is easily damaged by heat, can be placed on solder parts with electromagnetic shielding performed, and an electronic device B, which is relatively resistant to heat (higher heat resistance than electronic device A), can be placed in a portion without electromagnetic shielding performed. As a result, depending on the type of electronic device, it is possible to efficiently perform solder mounting while suppressing thermal damage to the electronic device. In addition, the above-mentioned low-temperature solder can be used for solder parts with electromagnetic shielding performed. In this way, by using solder that melts more easily at lower temperatures in solder parts with electromagnetic shielding performed, it is possible to suppress thermal damage to electronic devices that are in contact with the solder parts with electromagnetic shielding performed, and it is also possible to sufficiently increase the strength of the solder bond.

In yet another embodiment of the mounting method of the present invention (hereinafter referred to as Embodiment 3), in a case where conductive solder parts without electromagnetic shielding performed are heated and melted by the above-described magnetic field heating, the design is such that the conductivity of the solder parts is weakened to a certain extent by the heating and melting. Thus, as conductive solder parts without electromagnetic shielding performed are heated and melted, it is possible to increase the efficiency of magnetic field heating over time of solder parts with electromagnetic shielding performed. As a result, it becomes possible to heat and melt the solder parts with electromagnetic shielding performed under lower temperature heating or shorter heat treatment conditions. This form will be described in more detail.

On the mounting board, the solder parts with electromagnetic shielding performed are in a state where the irradiated microwaves are blocked or weakened. However, as the present inventors proceeded with their investigation, the following facts were discovered.

First, when a mounting board, on which solder parts with electromagnetic shielding performed and solder parts without electromagnetic shielding performed are formed on a base, is subjected to magnetic field heating of a microwave standing wave, while solder parts without electromagnetic shielding performed can be instantaneously and efficiently heated and melted, solder parts with electromagnetic shielding performed can be kept in a state where heating is not performed or is suppressed. This is as described above.

On the other hand, in a case where a mounting board, on which only solder parts with electromagnetic shielding performed are placed, is subjected to magnetic field heating of microwave standing waves, it has been discovered that the internal solder parts can be heated with high efficiency even though electromagnetic shielding is performed. This will be shown as an experimental example in the “Examples” section below. In other words, as the number of objects to be heated by the magnetic field that are present in a portion without electromagnetic shielding performed decreases, the magnetic field energy enters the inside of the electromagnetic shielding where the objects to be heated by the magnetic field (solder) are present.

By applying this phenomenon, the following becomes possible. In other words, in a case where conductive solder parts without electromagnetic shielding performed are heated and melted by the magnetic field heating described above, by designing the solder parts so that the electrical conductivity of the solder parts is weakened by this heating and melting, it becomes possible over time to increase the magnetic field energy that reaches the solder parts with electromagnetic shielding performed. Therefore, it becomes possible to heat and melt the solder parts with electromagnetic shielding performed under milder conditions.

As a method of designing a solder so that the conductivity of the solder part weakens by heating and melting, there is a method of performing a process of laminating the solder part or mixing the solder part with an element that chemically reacts with the solder in advance of heating, and then causing the solder and the element to chemically react when heating and melting to convert the solder to a different compound. Examples of elements to be chemically reacted with the solder include oxygen, nitrogen, sulfur, phosphorus, silicon, aluminum, iron, nickel, copper, silver, lead, bismuth, antimony, and the like. A design is possible in which by performing a process of laminating the solder with an organic compound or an inorganic compound including such an element as a thin film, a process of mixing the compound with the solder as a powder, a process of mixing the compound with the solder as a liquid, or the like, the conductivity of at least a portion of the solder part can be weakened by heating and melting the solder part by magnetic field heating.

Note that the degree to which the conductivity is weakened can be appropriately set according to the purpose. Conductivity of the solder may be maintained to some extent so that electrical connection can be maintained, or in a case where the purpose is only to immobilize electronic devices, the conductivity may be weakened to such an extent that the solder substantially no longer exhibits conductivity. In addition, by combining control of the energy of the microwaves to be irradiated and control of the heating time, it becomes possible to more flexibly adjust the amount of magnetic field energy that reaches the inside of the electromagnetic shielding.

In this way, with the mounting method of the present invention, by using magnetic field heating by microwave irradiation, it becomes possible to perform solder mounting while appropriately controlling the thermal history of an individual electronic device depending on the type (heat resistance) of the electronic device. That is, the mounting method of the present invention includes forms that will be described below.

A form in which, of the plurality of solder parts, solder parts without electromagnetic shielding performed are heated and melted by the action of a magnetic field of a standing wave created by microwave irradiation, then, of the plurality of solder parts, solder parts with electromagnetic shielding performed are heated and melted under milder conditions (heating at a lower temperature and/or heating for a shorter time) (Embodiments 1 to 3).

A form in which, of the plurality of solder parts, solder parts without electromagnetic shielding performed are heated and melted by the action of a magnetic field of a standing wave created by microwave irradiation, and of the plurality of solder parts, solder parts with electromagnetic shielding performed are also heated and melted under milder conditions due to the action of the magnetic field of the standing wave (Embodiments 2 and 3).

The mounting method of the present invention can also be a combination of Embodiment 1 and Embodiment 2 described above. For example, a form is possible in which, of the plurality of solder parts, solder parts without electromagnetic shielding performed are heated and melted by the action of a magnetic field of a standing wave created by microwave irradiation, of the plurality of solder parts, for some of the solder parts with electromagnetic shielding performed, the electromagnetic shielding is adjusted so that the solder parts are not heated and melted, and for the remaining solder parts with electromagnetic shielding performed, the electromagnetic shielding is adjusted so that the magnetic field energy reaches the solder parts even though it is weakened, and solder mounting of electronic devices under milder conditions is performed while suppressing thermal damage to the electronic devices.

In a preferred embodiment of the mounting method of the present invention, the base has an electrode part, the electronic devices also have an electrode part, the heated and melted solder parts are solidified, and the electrode part of the base and the electrode parts of the electronic devices are electrically connected via the solidified solder parts.

In addition, regarding the mounting method described above, the present invention provides a partially shielded board for mounting electronic devices that includes a base, a plurality of solder parts on the base, and a plurality of electronic devices corresponding to the plurality of solder parts and arranged in contact with the plurality of solder parts, and electromagnetic shielding is performed for some of the solder parts of the plurality of solder parts.

Next, a preferred form of a microwave heating apparatus used in the mounting method of the present invention will be explained; however, the present invention is not limited to the form using the microwave heating apparatus described below, except as specified in the present invention. Moreover, the microwave heating apparatus itself described below is already known, and in addition to what is described below, reference can be made to, for example, WO 2021/095723 A.

### [Microwave Heating Apparatus]

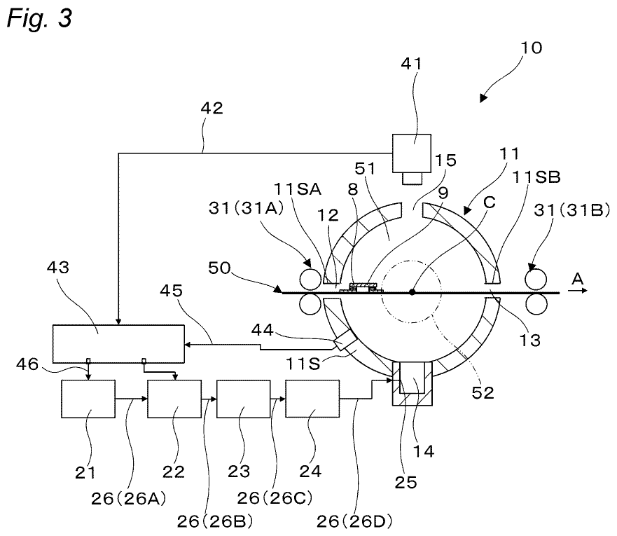

FIG. 3 is an explanatory diagram schematically showing an outline of a microwave heating apparatus. Therefore, some components may be omitted in FIG. 3 for convenience of explanation.

As shown in FIG. 3, a microwave heating apparatus 10 includes a cavity resonator (hereinafter also referred to as the (cylindrical) cavity resonator) 11 having a microwave irradiation space 51. The cavity resonator 11 may be a cylindrical type or a polygonal tube type having two parallel surfaces facing each other with a tube central axis as the center. That is, it is only necessary that a standing wave having a magnetic field strength maximum and uniform on a central axis C of the cavity resonator 11 can be formed. The following describes the cylindrical cavity resonator.

The cavity resonator 11 shown in FIG. 3 forms a standing wave in, for example, TM₁₁₀ mode where the magnetic field strength is maximum and uniform along a cylinder central axis (hereinafter referred to as the central axis) C. Hereinafter, the central axis of the cavity resonator 11 and the central axis of the microwave irradiation space 51 are used in the same meaning.

The cavity resonator 11 includes an inlet 12 provided in a barrel portion wall 11SA of the cavity resonator 11, and an outlet 13 provided in a barrel portion wall 11SB facing the barrel portion wall 11SA, the inlet 12 and the outlet 13 facing each other across the cylinder central axis C of the cavity resonator. It is preferable that the inlet 12 and the outlet 13 described above are formed in the shape of a slit with a width that allows the mounting board on which the electronic devices 9 are mounted via the solder parts 8 (some solder parts of the mounting board are performed with electromagnetic shielding, not shown in the drawing) to pass through. A transfer mechanism 31 that transfers the mounting board on which the electronic devices 9 are placed via the solder part 8 to a magnetic field region 52 in which an electric field becomes minimum and a magnetic field strength becomes maximum and uniform in the cavity resonator 11 is disposed. The magnetic field region 52 has the magnetic field strength decreased outward from the cylinder central axis C. In the drawing, a region in which the magnetic field strength is ¾ or more of the maximum value is schematically shown by a two-dot chain line as an example.

By the above-mentioned transfer mechanism 31, the mounting board on a support body 50 enters a microwave irradiation space 51 from the inlet 12, at least a part of the solder parts is heated and melted, and the processed mounted board is transferred out from the outlet 13.

For example, in a case of the cylindrical cavity resonator 11 where a standing wave in TM₁₁₀ mode is generated, a magnetic field region 52 is a space where the electric field strength is minimum and the magnetic field strength is maximum at the central axis C and the magnetic field is uniform along the central axis C.

A microwave generator 21 is disposed for the cavity resonator 11 to supply microwaves to the cavity resonator 11. The microwave frequency is generally 0.3 to 300 GHZ, and especially the S band ranging from 2 to 4 GHz is often used for the microwave frequency. Alternatively, 900 to 930 MHz, 5.725 to 5.875 GHz or the like may be used. However, other frequencies can also be used.

In the microwave heating apparatus 10, to the cavity resonator 11, the microwave generated by the microwave generator 21 is supplied to the microwave irradiation space 51 in the cavity resonator 11 from a microwave supply port 14, thereby forming a standing wave in the microwave irradiation space.

It is preferable that a microwave that is supplied from the microwave generator 21 is adjusted in frequency, and then supplied. The adjustment of the frequency allows stably controlling the magnetic field strength distribution of a standing wave formed in the cavity resonator 11 into a desired distribution state, and adjusting the intensity of the standing wave by the output of the microwave.

The frequency of a microwave that is supplied from the microwave supply port 14 can form a specific single-mode standing wave in the microwave irradiation space 51.

The constitution of the microwave heating apparatus 10 of the present invention will be described, in order.

### <Cavity Resonator>

The cylindrical cavity resonator (cavity) 11 used for the microwave heating apparatus 10 is not particularly limited as long as the cavity resonator 11 includes one microwave supply port 14 and forms a single-mode standing wave when a microwave is supplied. The microwave irradiation space 51 of the cavity resonator used for the present invention is not limited to the cylindrical type shown in the drawings. In other words, the cavity resonator may be a cavity resonator of not the cylindrical type but a polygonal tube type having two parallel surfaces facing each other with the central axis as the center. For example, the cavity resonator may be of a tube type of a regular even-sided polygon whose cross section in the direction perpendicular to the central axis is, for example, a square, a regular hexagon, a regular octagon, a regular dodecagon, or a regular hexadecagon, or a polygonal tube type of a shape obtained by crushing a tube type of a regular even-sided polygon between two surfaces facing across the central axis. In a case of the cavity resonator of the above polygonal tube type, corners inside the cavity resonator may be rounded. Moreover, a microwave irradiation space may be a cavity resonator having a space of, for example, a column or ellipsoid where the above roundness is increased, other than the above tube type.

Even such a polygon can realize effects similar to the cylindrical type (in other words, a standing wave whose magnetic field strength is maximum and uniform at the central axis can be formed).

A size of the cavity resonator 11 can be appropriately designed according to a purpose. The cavity resonator 11 desirably has a small electric resistivity. The cavity resonator 11 is usually made of a metal, and as an example, use can be made of aluminum, copper, iron, magnesium or an alloy of these; an alloy such as brass and stainless steel; or the like. Alternatively, a resin, ceramic, or metal surface may be coated by, for example, plating or vapor deposition with a material having a small electric resistivity. A material including silver, copper, gold, tin, or rhodium can be used for the coating.

### <Transfer Mechanism>

A transfer mechanism 31 preferably includes a supply-side transfer unit 31A, a sending-side transfer unit 31B, or both of them.

Alternatively, the supply part 31, the inlet 12, and the outlet 13 may not be provided with the transfer mechanism 31. In this case, it is possible to place a base 6 in advance at a position where in the cavity resonator the magnetic field is maximum, treat the base 6 for an appropriate time, and then stop a microwave, open a part of the cavity resonator, and take out the base 6 if necessary.

Alternatively, it is also possible to move the cavity resonator itself without using a specific transfer mechanism as the supply part 31.

### <Microwave Supply>

It is preferable to use a microwave generator 21, a microwave amplifier 22, an isolator 23, an impedance matcher 24, and an antenna 25, each for supplying the microwave.

The microwave supply port 14 is provided in or near a wall surface (an inner surface of the cylinder) parallel to the central axis C of the cavity resonator 11. In one embodiment, the microwave supply port 14 includes the antenna 25 that can apply a microwave. FIG. 3 shows the microwave supply port 14 using a coaxial waveguide converter. In this case, the antenna 25 is an electric field driven monopole antenna. At this point, an iris (not illustrated) may be used as an appropriate opening between the microwave supply port 14 and the cavity resonator 11 to effectively form a standing wave. Moreover, the antenna may be installed directly on the cavity resonator 11 without using the wave guide tube 14. In this case, a loop antenna (not illustrated) serving as a magnetic field driven antenna may be installed in or near a side wall of the cavity resonator. Alternatively, it is also possible to install an electric field driven monopole antenna on a top surface or undersurface of the cavity resonator.

The antenna 25 receives the supply of a microwave from the microwave generator 21. Specifically, it is preferable that the microwave amplifier 22, the isolator 23, the matcher 24, and the antenna 25 are connected sequentially to the microwave generator 21. Cable 26 (26A, 26B, 26C and 26D) is used for each connection.

For example, a coaxial cable is used for each cable 26. In this configuration, a microwave emitted from the microwave generator 21 is supplied by the antenna 25 from the microwave supply port 14 into the microwave irradiation space 51 in the cavity resonator 11 via each cable 26.

### [Microwave Generator]

As the microwave generator 21 for use in the microwave heating apparatus 10 of the present invention, for example, use can be made of the microwave generator, such as a magnetron, or the microwave generator using a solid-state semiconductor device. From the viewpoint of capable of finely adjusting the microwave frequency, it is preferable to use the VCO (voltage-controlled oscillator), VCXO (voltage-controlled crystal oscillator), or PLL (phase-locked loop) oscillator.

### [Microwave Amplifier]

The microwave heating apparatus 10 includes a microwave amplifier 22. The microwave amplifier 22 has the function of amplifying the output of a microwave generated by the microwave generator 21. The configuration is not particularly restricted. However, for example, it is preferable to use a solid-state semiconductor device including a high-frequency transistor circuit.

### [Isolator]

The microwave heating apparatus 10 includes an isolator 23. The isolator 23 prevents the influence of a reflected wave generated within the cavity resonator 11 and protects the microwave generator 21. That is, the isolator 23 causes microwaves to be supplied in one direction (the antenna 25 direction). If there is no risk that the microwave amplifier 22 and the microwave generator 21 are damaged by reflected waves, it is not necessary to install the isolator.

### [Matcher]

The microwave heating apparatus 10 includes the matcher 24. The matcher 24 matches (adjusts) the impedance from the microwave generator 21, microwave amplifier 22 and the isolator 23 and the impedance of the antenna 25. If there is no risk that the microwave amplifier 22 and the microwave generator 21 are damaged even when a reflected wave is generated due to a mismatch, or if an adjustment can be made so as to avoid the mismatch, it is not necessary to install the matcher.

### <Control System>

The above microwave heating apparatus 10 is provided with a thermal image measurement apparatus (thermo-viewer) 41, or a radiation thermometer (not illustrated), which measures the temperature. The cavity resonator 11 is preferably provided with a window 15 for measuring the temperature distribution inside the cavity resonator 11 with the thermal image measurement apparatus 41 or radiation thermometer (not illustrated). A measurement image of the temperature distribution measured by the thermal image measurement apparatus 41, or the temperature information measured by the radiation thermometer, is transmitted to a control unit 43 via a cable 42.

Furthermore, the barrel wall 11S of the cavity resonator 11 is preferably provided with an electromagnetic wave sensor 44. A signal in accordance with electromagnetic field energy in the resonator 11 detected by the electromagnetic wave sensor 44 is transmitted to the control unit 43 via a cable 45. The control unit 43 can detect the formation state (resonance state) of a standing wave generated in the microwave irradiation space 51 of the cavity resonator 11 on the basis of the signal of the electromagnetic wave sensor 44. When a standing wave has been formed, that is, when resonance is occurring, the output of the electromagnetic wave sensor 44 increases. The oscillatory frequency of the microwave generator 21 is adjusted in such a manner as to maximize the output of the electromagnetic wave sensor 44. Accordingly, it is possible to control the microwave frequency in such a manner as to agree with the resonance frequency of the cavity resonator 11.

In the control unit 43, the frequency of a microwave at which a standing wave of a fixed frequency occurs in the cavity resonator 11 can be fed back to the microwave generator 21 via a cable 46 on the basis of the detected frequency. The control unit 43 can precisely control the frequency of a microwave supplied from the microwave generator 21 on the basis of the feedback. A standing wave can be stably generated in the cavity resonator 11 in this manner. Moreover, the control unit 43 instructs the microwave amplifier 22 to output a microwave; accordingly, it is possible to make an adjustment in such a manner as to be able to supply a microwave of a fixed output to the antenna 25. Alternatively, it is also possible to adjust the attenuation factor of an attenuator (not illustrated) installed between the microwave generator 21 and the microwave amplifier 22 on an instruction of the control unit 43 without changing the amplification factor of the microwave amplifier 22. Feedback control may be performed on a microwave output to adjust the temperature of an object to be heated to a target temperature on the basis of an instructed value of the thermal image measurement apparatus 41 or the radiation thermometer. When an apparatus that can emit a large output, such as a magnetron, is used as the microwave oscillator 21, the control unit 43 may instruct the microwave generator 21 to adjust the microwave output.

As a control method that does not use the electromagnetic wave sensor 44, the magnitude of a reflected wave of the cavity resonator 11 may be measured to use a measurement value. The isolation amount obtained from the isolator 23 can be used to measure a reflected wave. The frequency of the microwave generator is adjusted in such a manner as to minimize a reflected wave signal; accordingly, microwave energy can be efficiently supplied to the cavity resonator 11.

In the microwave heating apparatus 10, the frequency of the standing wave is not particularly limited as long as the standing wave can be formed in the cavity resonator 11. As a mode of forming a maximum region of the magnetic field strength at the central axis C, TMₙ₁₀ (n is an integer of 1 or more) modes (for example, modes of TM₂₁₀, TM₃₁₀) and TE₁₀ₙ (n is an integer of 1 or more) modes are included. A standing wave in TM₁₁₀ is preferable in the respect that the portion of the maximum magnetic field strength can be efficiently formed along the central axis C of the cavity resonator 11.

In the case of a TE₁₀ₙ (n is an integer of 1 or more) mode, a TE₁₀₁ mode where n=1 is the most preferable, or TE₁₀₂ and TE₁₀₃ modes are also acceptable.

The cavity resonator 11 is ordinarily designed so that the resonance frequency is within an ISM (Industry Science Medical) band. However, when including a mechanism capable of suppressing the level of the electromagnetic wave radiated from the cavity resonator 11 or the whole apparatus so as not to affect the safety to the surroundings, the communication, and the like, the design with the frequency other than the ISM band is allowed.

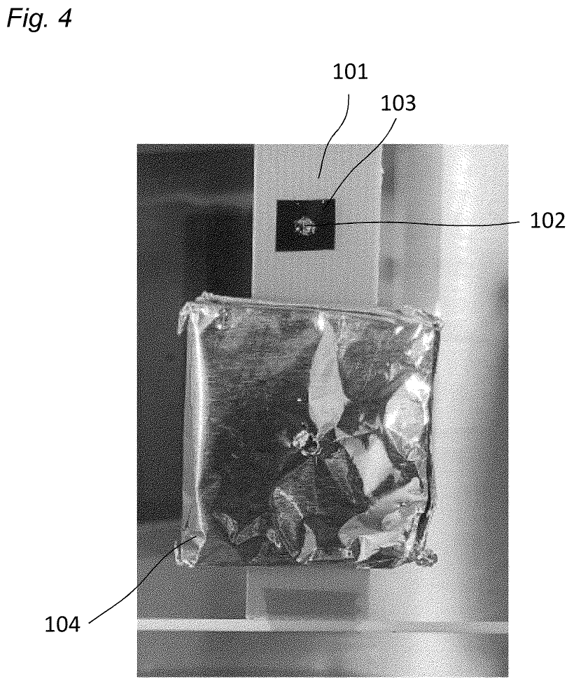

The mounting method of the present invention can also be carried out by applying a solder mounting apparatus including the microwave heating apparatus 10. For a specific example of the configuration of the solder mounting apparatus, for example, the form shown in FIG. 4 of WO 2021/095723 A can be referred to.

### EXAMPLES

The present invention will be explained in more detail below by showing experimental examples. The experimental examples are provided to facilitate understanding of the present invention, but the present invention is not limited to these forms in any way.

### Experimental Example 1-1

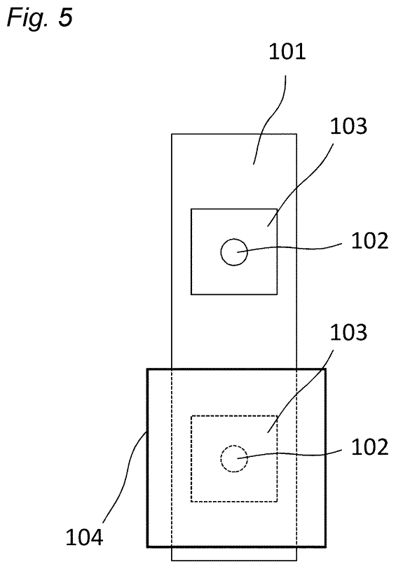

Two 5 mm square n-type silicon wafers 103 on which 0.2 g of solder paste 102 (Senju Metal Industry Co., Ltd.: M705) was placed were prepared. One of the wafers was placed in an aluminum foil box 104 having a thickness of 160 μm, a length of 30 mm, a width of 20 mm, and a hole with a diameter of 1 mm in the center of an upper portion. Both the silicon wafer 103 with solder paste 102 and placed inside the aluminum foil box 104 and the other silicon wafer 103 with solder paste 102 (no aluminum foil box) were placed on a glass epoxy resin substrate 101 (FR-4). A photograph showing this state is shown in FIG. 4. In addition, FIG. 5 is an explanatory diagram schematically showing the photograph of FIG. 4 with the inner state of the aluminum foil box also visible.

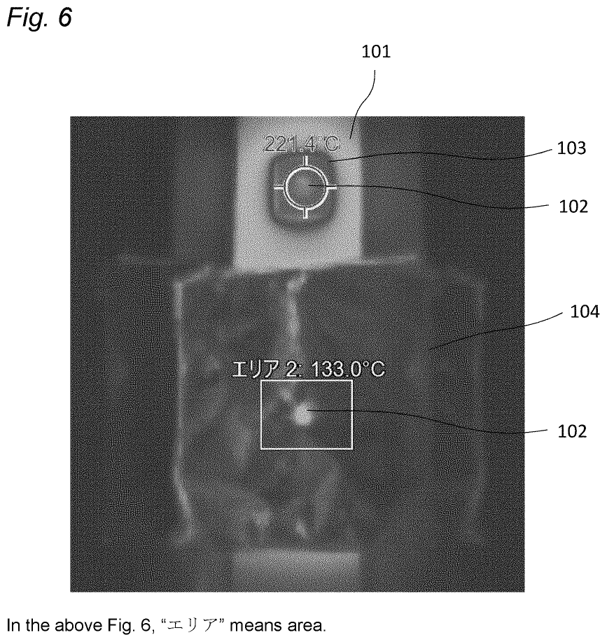

The glass epoxy resin substrate 101 described above was placed at the center of a cylindrical cavity resonator. A temperature distribution when a microwave with an output of 30 W was introduced into the cavity resonator to form a TM110 mode standing wave was measured from an upper surface of the glass epoxy resin substrate 101 using a thermo camera, and measurements were made for both the silicon wafer 103 (without the aluminum foil box) and the silicon wafer 103 placed inside the aluminum foil box on the substrate. The results are shown in FIG. 6.

From FIG. 6, it can be seen that a portion of the solder paste not placed inside the aluminum foil box reached a high temperature of 221.4° C. On the other hand, the solder paste inside the aluminum foil box (inside the electromagnetic shielding) was maintained at a relatively low temperature of 133° C. That is, it can be seen that the aluminum foil box functions as electromagnetic shielding. Here, this aluminum foil box has a hole with a diameter of 1 mm as described above. It is thought that microwaves do not pass through a fine hole with a diameter of 1 mm, but in reality, mild microwave heating occurred. In other words, it can also be seen that magnetic field heating may be performed under milder conditions by controlling the state of the electromagnetic shielding.

### Experimental Example 1-2

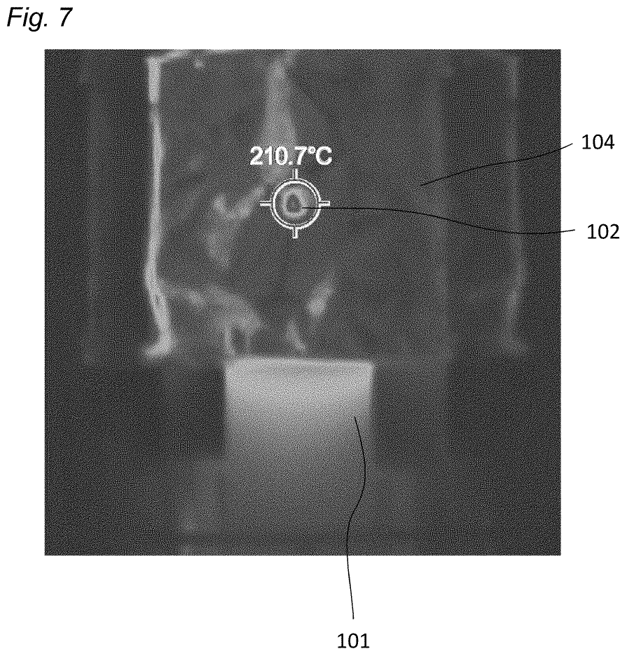

A 5 mm square n-type silicon wafer containing 0.2 g of solder paste 102 (Senju Metal Industry Co., Ltd.: M705) was placed inside an aluminum foil box 104 with a thickness of 160 μm, length of 30 mm, width of 20 mm, and a hole with a diameter of 1 mm in the center of the upper portion. Only the silicon wafer 103 with the solder paste 102 and that was placed inside the aluminum foil box 104 was placed on a glass epoxy resin substrate 101 (FR-4). In this state, the glass epoxy resin substrate 101 was placed at the center of a cylindrical cavity resonator. A microwave with an output of 30 W was introduced into the cavity resonator to form a TM₁₁₀ mode standing wave, and the temperature distribution was measured in the same manner as above. A photograph showing the results is shown in FIG. 7.

From FIG. 7 it can be seen that the solder paste placed inside the aluminum foil box reached a high temperature of 210.7° C. in the absence of a solder paste portion not provided with the aluminum foil box. In other words, it can be seen that the magnetic field energy acts intensively on the solder resist 102 inside the aluminum foil box.

### Experimental Example 2-1

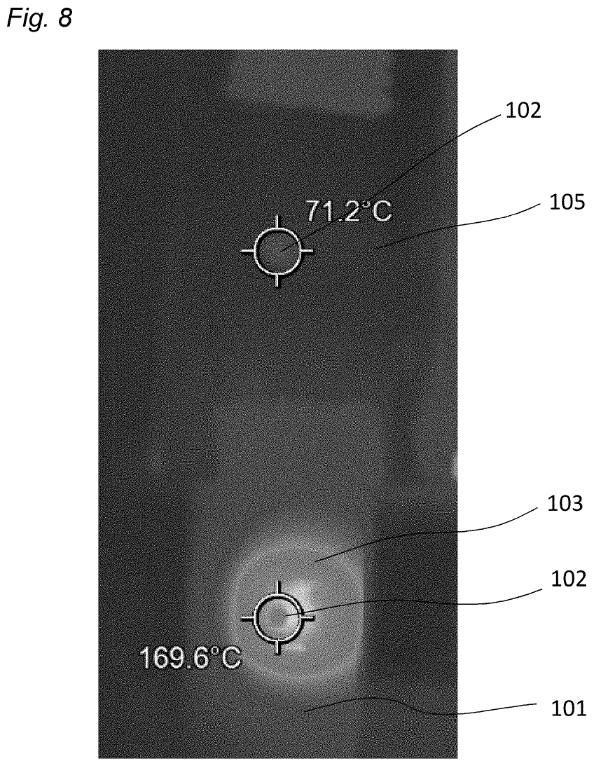

Two 5 mm square n-type silicon wafers 103 on which 0.2 g of solder paste 102 (Senju Metal Industry Co., Ltd.: M705) was placed were prepared. One of the wafers was placed in a copper plate box 105 having a thickness of 100 μm, a length of 30 mm, a width of 20 mm, and a hole with a diameter of 1 mm in the center of an upper portion. Both the silicon wafer with solder paste 102 and placed inside the copper plate box 105 and the other silicon wafer 103 with solder paste 102 (no copper plate box) were placed on a glass epoxy resin substrate 101 (FR-4). In this state, the glass epoxy resin substrate 101 was placed at the center of a cylindrical cavity resonator. A microwave with an output of 30 W was introduced into the cavity resonator to form a TM₁₁₀ mode standing wave, and the temperature distribution was measured in the same manner as above. The result is shown in FIG. 8.

From FIG. 8, it can be seen that a portion of the solder paste not placed inside the copper plate box 105 reached a high temperature of 169.6° C. On the other hand, the solder paste inside the copper plate box 105 (inside the electromagnetic shielding) was gently heated to 71.2° C. That is, it can be seen that the copper plate box 105 functions as electromagnetic shielding. Here, this copper plate box has a hole with a diameter of 1 mm as described above. It is thought that microwaves do not pass through a fine hole with a diameter of 1 mm, but in reality, mild microwave heating occurred. In other words, it can also be seen that magnetic field heating may be performed under milder conditions by controlling the state of the electromagnetic shielding.

### Experimental Example 2-2

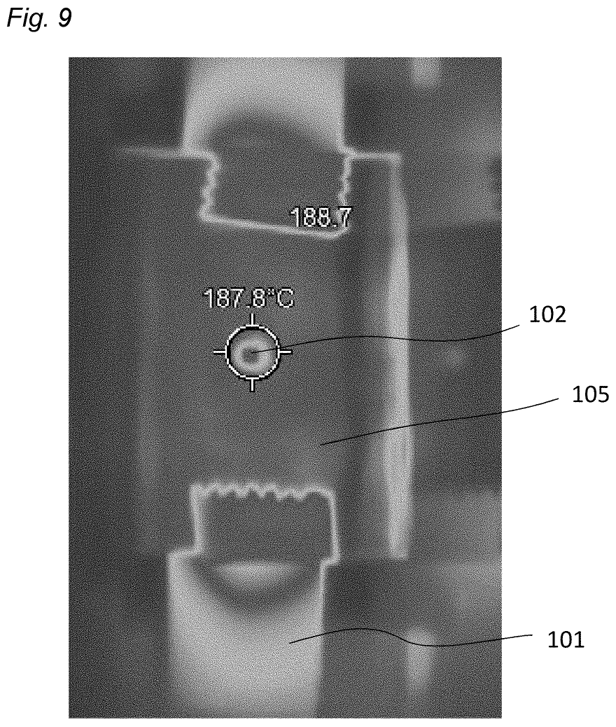

A 5 mm square n-type silicon wafer containing 0.2 g of solder paste 102 (Senju Metal Industry Co., Ltd.: M705) was placed inside a copper plate box 105 with a thickness of 100 μm, length of 30 mm, width of 20 mm, and a hole with a diameter of 1 mm in the center of the upper portion. Only the silicon wafer with the solder paste 102 and that was placed inside the copper plate box 105 was placed on a glass epoxy resin substrate 101 (FR-4). In this state, the glass epoxy resin substrate 101 was placed at the center of a cylindrical cavity resonator. A microwave with an output of 30 W was introduced into the cavity resonator to form a TM₁₁₀ mode standing wave, and the temperature distribution was measured in the same manner as above. The result is shown in FIG. 9.

From FIG. 9 it can be seen that the solder paste placed inside the copper plate box was heated to 187.8° C. in the absence of a solder paste portion not provided with the copper plate box. In other words, it can be seen that the magnetic field energy acts intensively on the solder resist inside the copper plate box.

From the results of the above experimental examples, it was found that by combining magnetic field heating by a microwave standing wave and partial electromagnetic shielding, and by appropriately adjusting the microwave irradiation energy, it becomes possible to freely control the heating state for each individual solder part of a plurality of solder parts during solder mounting.

Having described our invention as related to the embodiments and Examples, it is our intention that the invention not be limited by any of the details of the description, unless otherwise specified, but rather be construed broadly within its spirit and scope as set out in the accompanying claims.

This application claims priority on Patent Application No. 2021-116207 filed in Japan on Jul. 14, 2021, which is entirely herein incorporated by reference.

### DESCRIPTION OF SYMBOLS

1 Base
2 Solder
3 Electronic device
4 Electromagnetic shielding
5 Microwave
10 Microwave heating apparatus
11 Cavity resonator
12 Inlet
13 Outlet
14 Microwave supply port
15 Window
21 Microwave generator
22 Microwave amplifier
23 Isolator
24 Matcher
25 Antenna
26, 42, 45, 46 Cable
31 Transfer mechanism
31A Supply-side transfer unit
31B Sending-side transfer unit
41 Thermal image measurement apparatus
43 Control unit
44 Electromagnetic wave sensor
50 Support
52 Magnetic field region
A Transfer direction
C Cavity central axis (central axis)
101 Glass epoxy resin substrate
102 Solder paste
103 Silicon wafer
104 Aluminum foil box
105 Copper plate box

1. A method of mounting electronic devices, comprising the steps of:
irradiating with microwaves a board for mounting electronic devices including a base, a plurality of solder parts on the base, and a plurality of electronic devices corresponding to the plurality of solder parts placed in contact with the plurality of solder parts, the microwave irradiation is performed in a state in which electromagnetic shielding is performed for some of the plurality of solder parts; and
heating and melting at least the solder parts for which the electromagnetic shielding is not performed by an action of a magnetic field of a standing wave formed by the microwave irradiation.

2. The method of mounting electronic devices according to claim 1, wherein, of the plurality of solder parts, the solder parts for which the electromagnetic shielding is not performed are heated and melted by the action of the magnetic field of the standing wave, and then, of the plurality of solder parts, the solder parts for which the electromagnetic shielding is performed are heated and melted under a milder heating condition than a heating condition of the solder parts for which the electromagnetic shielding is not performed.

3. The method of mounting electronic devices according to claim 1, wherein, of the plurality of solder parts, the solder parts for which the electromagnetic shielding is not performed are heated and melted by the action of the magnetic field of the standing wave, and of the plurality of solder parts, the solder parts for which the electromagnetic shielding is performed are also heated and melted by the action of the magnetic field of the standing wave under a milder heating condition than a heating condition of the solder parts for which the electromagnetic shielding is not performed.

4. The method of mounting electronic devices according to claim 2, wherein a low-temperature solder is used for the solder parts for which the electromagnetic shielding is performed of the plurality of solder parts.

5. The method of mounting electronic devices according to claim 1, wherein the base includes an electrode part, the electronic devices also include an electrode part, the heated and melted solder parts are solidified, and the electrode part of the base and the electrode parts of the electronic devices are electrically connected via the solidified solder parts.

6. The method of mounting electronic devices according to claim 1, wherein the electromagnetic shielding contains metal materials.

7. The method of mounting electronic devices according to claim 1, wherein the standing wave is TMₙ₁₀ (where n is an integer of 1 or more) mode or TE₁₀ₙ (where n is an integer of 1 or more) mode.

8. A partially shielded board for mounting electronic devices, comprising:
a base,
a plurality of solder parts on the base, and
a plurality of electronic devices corresponding to the plurality of solder parts and placed in contact with the plurality of solder parts,
wherein electromagnetic shielding is performed for some of the solder parts of the plurality of solder parts.

9. The partially shielded board for mounting electronic devices according to claim 8, wherein, by action of a magnetic field of a standing wave of microwave waves, at least the solder parts for which the electromagnetic shielding is not performed are heated and melted.

10. The partially shielded board for mounting electronic devices according to claim 8, wherein the solder parts for which the electromagnetic shielding is performed contains a low-temperature solder.

11. The method of mounting electronic devices according to claim 3, wherein a low-temperature solder is used for the solder parts for which the electromagnetic shielding is performed of the plurality of solder parts.
